(19) United States
(12) Patent Application Publication
(10) Pub. No.: US 2008/0199653 A1
(43) Pub. Date: Aug. 21, 2008

(54) Method of forming two-dimensional pattern by using nanospheres

(75) Inventors: Hao-Chung Kuo, North Hsin-Tsu City (TW); Shi Wun Tong, Hong Kong (HK); Hung-Shen Chu, Hsinchu (TW); Yong Cai, Nanjing (CN)

Correspondence Address: MERCHANT & GOULD PC, P.O. BOX 2903, MINNEAPOLIS, MN, 55402-0903, US

(73) Assignee: Hong Kong Applied Science and Technology Research Institute Co. Ltd., Shatin (CN)

(21) Appl. No.: 11/897,194

(22) Filed: Aug. 28, 2007

(30) Foreign Application Priority Data
Feb. 15, 2007 (CN) 200710080267.6

(51) Int. Cl. B32B 5/00; H01L 21/00

(52) U.S. Cl. 428/98; 438/29; 257/E21.001

(57) ABSTRACT

The present invention relates to a method of forming a two-dimensional pattern, which includes: dispersing a plurality of spheres on a substrate; using the spheres to form a mask on the substrate; etching the substrate; and removing the mask from the substrate. In addition, the present invention further relates to a method of processing a surface of a substrate, which includes: dispersing a plurality of spheres on the surface of the substrate; depositing a substance among the spheres; and removing the spheres to leave the deposited substance on the surface of the substrate. The method of the present invention achieves a quicker and simpler process with a lower cost. In addition, a light emitting device manufactured through the method of the present invention has preferred light extraction efficiency and a variable radiation field pattern.

### FIELD OF THE INVENTION

The present invention relates to a lithography method. More particularly, the present invention relates to a method of forming a two-dimensional pattern by using nanospheres.

### DESCRIPTION OF THE PRIOR ART

A light-emitting diode (LED) is a commonly used photoelectric element. Generally, the LED with a roughened surface or the LED with a two-dimensional photonic crystal has higher light extraction efficiency than the LED with a smooth surface. The common techniques for forming the two-dimensional photonic crystal on the surface of the LED include the following three types: electron beam lithography (EBL), nanoimprint lithography (NIL), and copolymer lithography (CPL).

Recently, the method of using the EBL to form a two-dimensional photonic crystal on the surface of the LED substrate has been disclosed in many patents, for example, US Patent Publication Nos. 2006/0027815 and 2005/0285132. Generally, in the prior art, a layer of photoresist is coated on the LED substrate. Next, an electron beam is used to irradiate a part of the photoresist. Then, once the part of the irradiated photoresist is removed, the remained part of the photoresist can be used as an etching mask. Then, after a

### FIELD OF THE INVENTION

The present invention relates to a lithography method. More particularly, the present invention relates to a method of forming a two-dimensional pattern by using nanospheres.

### DESCRIPTION OF THE PRIOR ART

A light-emitting diode (LED) is a commonly used photoelectric element. Generally, the LED with a roughened surface or the LED with a two-dimensional photonic crystal has higher light extraction efficiency than the LED with a smooth surface. The common techniques for forming the two-dimensional photonic crystal on the surface of the LED include the following three types: electron beam lithography (EBL), nanoimprint lithography (NIL), and copolymer lithography (CPL).

Recently, the method of using the EBL to form a two-dimensional photonic crystal on the surface of the LED substrate has been disclosed in many patents, for example, US Patent Publication Nos. 2006/0027815 and 2005/0285132. Generally, in the prior art, a layer of photoresist is coated on the LED substrate. Next, an electron beam is used to irradiate a part of the photoresist. Then, once the part of the irradiated photoresist is removed, the remained part of the photoresist can be used as an etching mask. Then, after a reactive ion etching (RIE) is performed and the mask is removed, a two-dimensional pattern is formed on the LED substrate. The method of using the EBL to form the two-dimensional pattern on the surface of the LED substrate has the advantage of high accuracy, and the accuracy can reach up to 1-2 nanometers, but the disadvantage lies in the facts that the equipment is too expensive, only serial patterns are generated, and the process is time consuming.

The method of using the NIL to form a two-dimensional photonic crystal on the surface of the LED substrate can be obtained with reference to the relevant records of US Patent Publication No. 2005/0173717 and U.S. Pat. No. 7,074,631. The main steps include: firstly, the EBL is used to fabricate an stamp mold, and then, the mold is pressed on the substrate coated with the UV curable resist, which then is irradiated by ultraviolet rays. Once the substrate is separated from the mold, the substrate with the embossed pattern is obtained. The method of using the NIL to form the two-dimensional photonic crystal can achieve the nano-level accuracy, and even higher than that can be achieved by the EBL, but the disadvantage lies in the facts that the mold has a high cost and the lifecycle is not long. In addition, during the practical operation, the polymer on the substrate cannot totally fill up the gaps of the mold, or may stick on the gaps of the mold and cannot be shaken out.

U.S. Pat. No. 7,037,738 and No. 6,468,823 disclose a method of using the CPL to form a two-dimensional photonic crystal on a surface of an LED substrate, which mainly includes: a specific solvent mixed using polystyrene and polymethyl methacrylate is uniformly coated on the LED substrate, and then, the substrate is continuously heated for 4 hours in an environment filling up with N2 at a high temperature of 210° C., so that a phase separation occurs between polystyrene and polymethyl methacrylate. Next, the RIE is used to remove the polymethyl methacrylate. Finally, an etching process is performed by using the remaining polystyrene as the mask. Once the mask is removed, the two-dimensional structure is obtained on the surface of the LED substrate. The method of using the CPL to form the two-dimensional photonic crystal has the disadvantages that a high temperature is required and it is quite time consuming during the phase separation process. In addition, the specific solvent must be used to dissolve polystyrene and polymethyl methacrylate.

To sum up, the above technical process is complicated and time consuming, and has a higher cost. A simple, quick, and cost saving method of forming the two-dimensional pattern is required.

### SUMMARY OF THE INVENTION

In order to eliminate the disadvantages of the prior art that the process is complicated and time consuming, and has a high cost, the present invention provides a simple, quick and cost-saving method of forming a two-dimensional pattern.

The present invention provides a simpler method of forming a two-dimensional photonic crystal on a surface of a photoelectric element.

The present invention further provides a method of easily roughing a surface of a photoelectric element substrate.

The present invention provides a method of forming a two-dimensional pattern in an embodiment, which includes: dispersing a plurality of spheres on a substrate; using the spheres to form a mask on the substrate; etching the substrate; and removing the mask from the substrate.

The present invention provides a method of processing a surface of a substrate in another embodiment, which includes: dispersing a plurality of spheres on the surface of the substrate; depositing a substance among the spheres; and removing the spheres to leave the deposited substance on the surface of the substrate.

According to the embodiments of the present invention, the arranging pattern of the nanospheres is used to form the two-dimensional pattern (e.g., the photonic crystal pattern) on the surface of the photoelectric element substrate, to roughen the surface of the substrate, or to form arc-shaped pits on the surface of the substrate. Therefore, the method provided by the present invention is much easier, quicker, and more cost saving than the methods of using EBL, NIL, and CPL in the prior art. In addition, the method provided by the present invention can further improve the light extraction efficiency and provide a variable radiation pattern.

In order to make the aforementioned and other objects, features, and advantages of the present invention more comprehensible, preferred embodiments accompanied with figures are described in detail below.

### BRIEF DESCRIPTION OF THE DRAWING

FIGS. 1A to 1E are schematic views of a method of forming a two-dimensional photonic crystal on a surface of a photoelectric element substrate according to a first preferred embodiment of the present invention;

FIGS. 2A to 2D are schematic views of a method of forming a two-dimensional photonic crystal on a surface of a photoelectric element substrate according to a second preferred embodiment of the present invention;

FIGS. 3A to 3E are schematic views of a method of forming a two-dimensional photonic crystal on a surface of a photoelectric element substrate according to a third preferred embodiment of the present invention;

FIGS. 4A to 4B are schematic views of a first embodiment of a method of forming a roughened surface on a photoelectric element substrate according to the present invention;

FIGS. 5A to 5C are schematic views of a second embodiment of a method of forming a plurality of arc-shaped pits on a surface of a substrate according to the present invention; and

FIGS. 6A and 6B are respectively a schematic view of a smooth surface of the photoelectric element substrate and a schematic view of a surface of the photoelectric element having arc-shaped pits.

### DETAILED DESCRIPTION

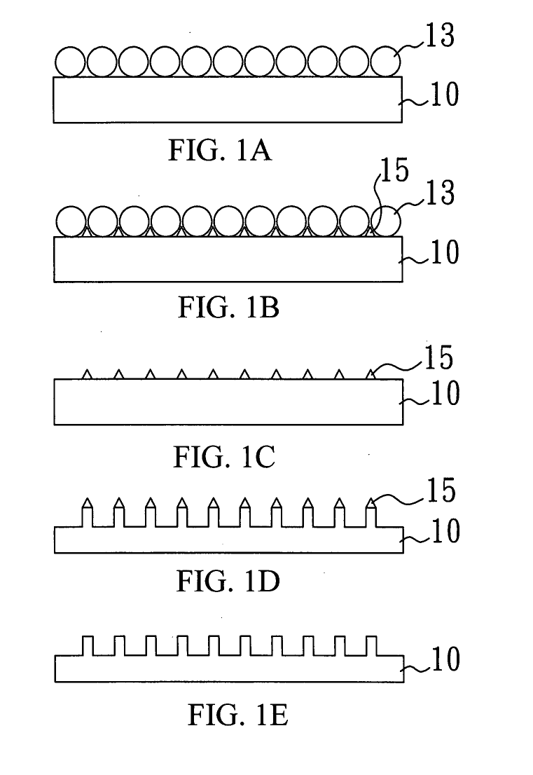

FIGS. 1A to 1E are schematic views of a method of forming a two-dimensional pattern (e.g., a photonic crystal pattern) on a surface of a photoelectric element substrate according to a first preferred embodiment of the present invention. The photoelectric element provided by the present invention can be an LED or a semiconductor laser. Firstly, as shown in FIG. 1A, a plurality of nanospheres 13 is closely arranged on a substrate 10 of the photoelectric element, and the material of the substrate 10 can be sapphire, SiC, Si, metal (e.g., Cu, Ag, Al), AlN, GaN, GaAs, AlInGaP or diamond with an epitaxial structure of the photoelectric element. Next, as shown in FIG. 1B, a metal material 15 is deposited among the spheres to act as the mask, and then, the nanospheres 13 are removed (as shown in FIG. 1C). Then, the RIE is preformed by using the mask (as shown in FIG. 1D). Finally, the metal material 15 is removed to form the two-dimensional pattern as shown in FIG. 1E on the substrate 10 of the photoelectric element.

In the embodiment of the present invention, the plurality of nanospheres can be arranged closely through the following ways. Firstly, a mixed liquid of the nanospheres and the water is coated on the substrate of the photoelectric element. Next, as the water is evaporated, the water molecules can draw the nanospheres close to each other, so as to reduce the surface tension of the water molecules. Therefore, once the water molecules are evaporated to a certain level, a plurality of nanospheres is automatically and closely arranged in mono-layers. In other words, the nanospheres are arranged in a manner of a two-dimensional pattern similar to a honeycomb.

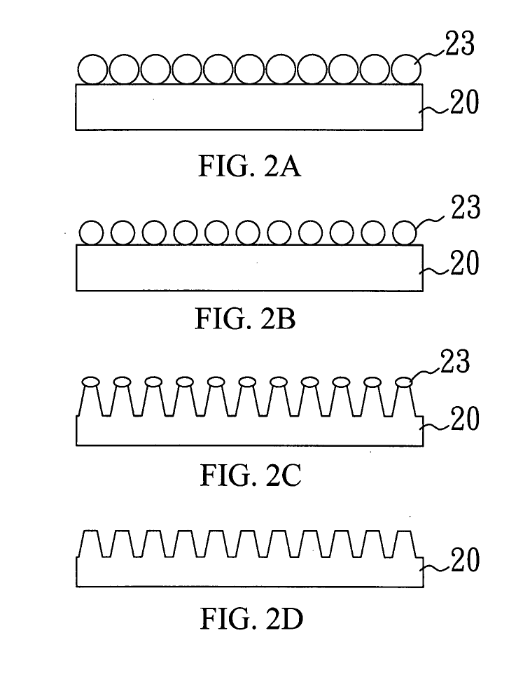

FIGS. 2A to 2D are schematic views of a method of forming a two-dimensional photonic crystal on a surface of a photoelectric element substrate according to a second preferred embodiment of the present invention. Firstly, as shown in FIG. 2A, a plurality of nanospheres 23 is closely arranged on the substrate 20 of the photoelectric element. Next, as shown in FIG. 2B, under the condition that the center position of the nanospheres 23 is not changed, the size of each nanoparticle 23 is shrunk by using the RIE. Then, the RIE is preformed by using the shrunk nanoparticle 23 as the mask (as shown in FIG. 2C). Finally, the shrunk nanospheres 23 are removed to form the two-dimensional pattern as shown in FIG. 2D on the substrate 20 of the photoelectric element.

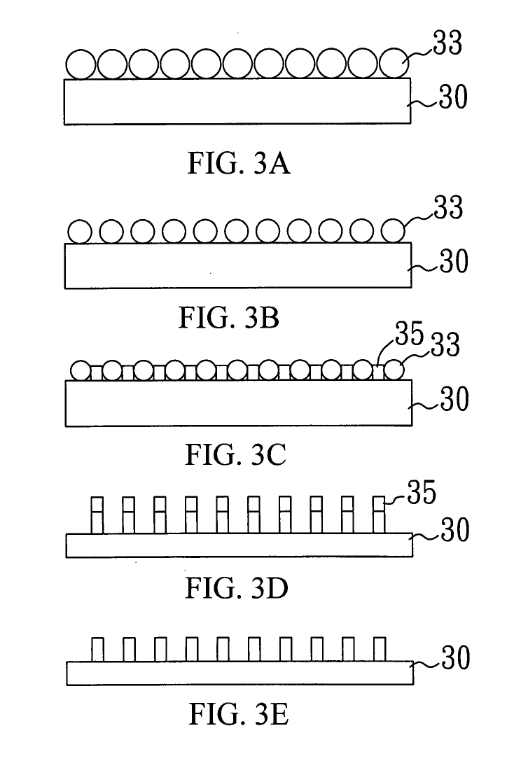

FIGS. 3A to 3E are schematic views of a method of forming a two-dimensional photonic crystal on a surface of a photoelectric element substrate according to a third preferred embodiment of the present invention. Firstly, as shown in FIG. 3A, a plurality of nanospheres 33 is closely arranged on the substrate 30 of the photoelectric element. Next, as shown in FIG. 3B, under the condition that the central position of the nanospheres 23 is not changed, the size of the nanospheres 33 is shrunk by using the RIE. Next, a metal material 35 is deposited among the nanospheres 33 (as shown in FIG. 3C). Then, the shrunk nanospheres 33 are removed and the RIE is preformed by using the metal material 35 as the mask (as shown in FIG. 3D). Finally, the metal material 35 is removed to form the two-dimensional pattern as shown in FIG. 3E on the substrate 30 of the photoelectric element.

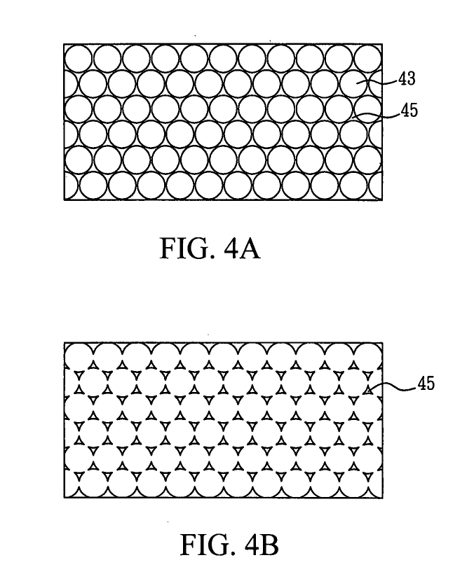

In addition, the present invention also provides a method of forming a roughened surface on the substrate of the photoelectric element. FIGS. 4A to 4B are schematic views of a method of forming a roughened surface on the substrate of the photoelectric element according to the embodiment of the present invention. As shown in FIG. 4A, firstly, a plurality of nanospheres 43 is closely arranged on a substrate, and a transparent optical material 45 is deposited among the spheres. Once the spheres 43 are removed, the two-dimensional array as shown in FIG. 4B is generated on the surface of the substrate, so as to achieve the objective of roughening the surface of the substrate.

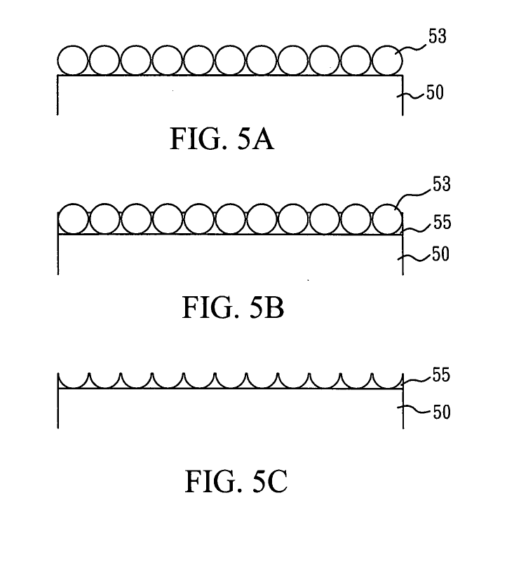

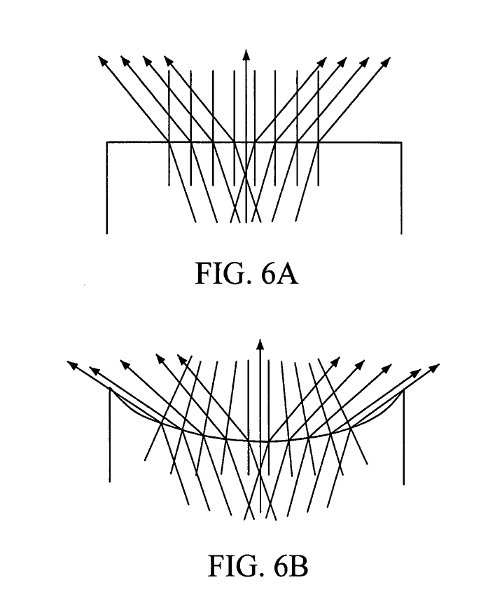

FIGS. 5A to 5C are schematic views of a second embodiment of a method of forming a plurality of arc-shaped pits on a surface of a substrate according to the present invention. Firstly, as shown in FIG. 5A, a plurality of nanospheres 53 is closed arranged on the substrate of the photoelectric element 50. Next, as shown in FIG. 5B, a hydrosol 55 is guided among the nanospheres 53. After the hydrosol 55 is set, the nanospheres 53 are removed to obtain a surface of the substrate having a plurality of arc-shaped pits (as shown in FIG. 5C). FIG. 6A is a schematic view of a smooth surface of the photoelectric element, and FIG. 6B is a schematic view of a surface of the photoelectric element having the arc-shaped pits. It is known from FIGS. 6A and 6B that the light-emitting angle for the surface of the photoelectric element substrate having the arc-shaped pits is larger than that of the smooth surface of the photoelectric element. In other words, the surface of the photoelectric element with the arc-shaped pits has more light rays being refracted, and the optical field pattern is relatively diversified. Therefore, it is known that the photoelectric element generated through the method as shown in FIGS. 5A to 5C can emit more light rays, that is, the light extraction efficiency of the photoelectric element can be improved, and a variable radiation pattern can be obtained.

To sum up, in the present invention, the arranging pattern of the nanospheres is used to form the two-dimensional photonic crystal on the surface of the photoelectric element substrate, to roughen the surface of the substrate, or to form the arc-shaped pits, so as to improve the light extraction efficiency, enlarge the light radiation angle, and provide the variable radiation pattern. Therefore, the method provided by the present invention not only has the nano-level accuracy, but it is also much easier, quicker, and more cost saving than the method of using the EBL, the NIL, and the CPL in the prior art.

It will be apparent to those skilled in the art that various modifications and variations can be made to the structure of the present invention without departing from the scope or spirit of the invention. In view of the foregoing, it is intended that the present invention cover modifications variations of this invention, provided that they fall within the scope of the following claims and their equivalents.

1. A method of forming a two-dimensional pattern, comprising:
dispersing a plurality of spheres on a substrate;
using the spheres to form a mask on the substrate;
etching the substrate; and
removing the mask from the substrate.

2. The method as claimed in claim 1, wherein the step of forming the mask comprises:
depositing a metal material among the spheres to act as the mask.

3. The method as claimed in claim 1, further comprising:
removing the spheres from the substrate after forming the mask.

4. The method as claimed in claim 2, wherein the step of forming the mask further comprises:
etching the spheres to shrink the spheres before depositing the metal material.

5. The method as claimed in claim 1, wherein the step of forming the mask comprises:
etching the spheres to shrink the spheres, and using the shrunk spheres as the mask.

6. The method as claimed in claim 1, wherein the etching is a reactive ion etching.

7. The method as claimed in claim 1, wherein the substrate is a substrate of a photoelectric element.

8. The method as claimed in claim 7, wherein the photoelectric element is a light emitting diode or a semiconductor laser.

9. The method as claimed in claim 7, wherein the material of the substrate is sapphire, SiC, Si, metal, AlN, GaN, GaAs, AlInGaP or diamond with an epitaxial structure of the photoelectric element.

10. The method as claimed in claim 1, wherein the two-dimensional pattern is two-dimensional photonic crystals or quasi-two-dimensional photonic crystals on a surface of the substrate of the photoelectric element.

11. A method of processing a surface of a substrate, comprising:
dispersing a plurality of spheres on the surface of the substrate;
depositing a substance among the spheres; and
removing the spheres to leave the deposited substance on the surface of the substrate.

12. The method as claimed in claim 11, wherein the substance is a transparent optical material.

13. The method as claimed in claim 11, wherein the substance is a hydrosol.

14. The method as claimed in claim 11, wherein the remaining deposited substance forms a roughened surface on the surface of the substrate.

15. The method as claimed in claim 11, wherein the remaining deposited substance forms a plurality of arc-shaped pits on the surface of the substrate.

16. The method as claimed in claim 11, wherein the substrate is a substrate of a photoelectric element.

17. The method as claimed in claim 16, wherein the photoelectric element is a light-emitting diode or a semiconductor laser.

18. The method as claimed in claim 16, wherein the material of the substrate is sapphire, SiC, Si, metal, AlN, GaN, GaAs, AlInGaP or diamond with an epitaxial structure of the photoelectric element.

19. A photoelectric element, comprising a substrate, wherein the surface of the substrate is processed by the method as claimed in claim 11.

20. A photoelectric element, comprising a substrate, wherein a surface of the substrate has a two-dimensional pattern processed by the method as claimed in claim 1.
